(19) United States
(12) Patent Application Publication
(10) Pub. No.: US 2024/0247152 A1
(43) Pub. Date: Jul. 25, 2024

(54) RESIN COMPOSITION, DISPLAY DEVICE MANUFACTURED USING THE SAME, AND MANUFACTURING METHOD OF THE DISPLAY DEVICE

(71) Applicant: Samsung Display Co., LTD., Yongin-si (KR)

(72) Inventors: Hyung Guen YOON, Yongin-si (KR); Suk Hoon KANG, Yongin-si (KR)

(21) Appl. No.: 18/415,444

(22) Filed: Jan. 17, 2024

(30) Foreign Application Priority Data
Jan. 18, 2023 (KR) 10-2023-0007346

(51) Int. Cl. C09D 5/16; C08F 220/24; C08F 220/28; C08F 220/38; C08F 222/02; C08F 222/10; C09D 133/02; C09D 133/16; C09D 135/02; H10K 59/12; H10K 59/122

(52) U.S. Cl. CPC C09D 5/1637; C08F 220/24; C08F 220/282; C08F 220/387; C08F 222/02; C08F 222/103; C09D 133/02; C09D 133/16; C09D 135/02; H10K 59/1201; H10K 59/122

(57) ABSTRACT

An embodiment provides a resin composition including a liquid repellent, where the liquid repellent includes a compound represented by Chemical Formula I below or a compound represented by Chemical Formula 2 below:

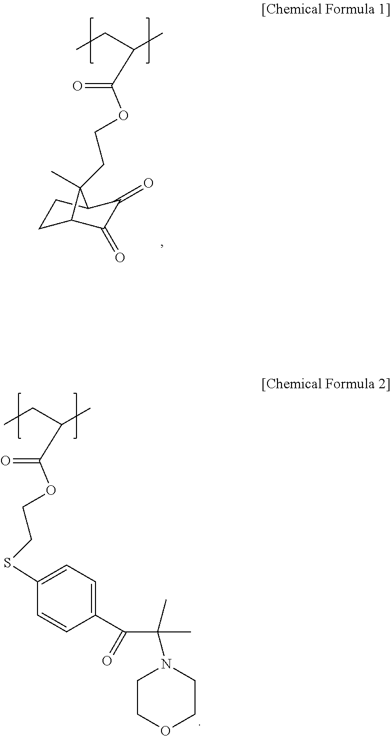

This application claims priority to Korean Patent Application No. 10-2023-0007346 filed on Jan. 18, 2023, and all the benefits accruing therefrom under 35 U.S.C. § 119, the content of which in its entirety is herein incorporated by reference.

### BACKGROUND

### (a) Technical Field

The present disclosure relates to a resin composition, a display device manufactured using the same, and a method for manufacturing the display device, and more particularly, to a resin composition and a display device manufactured using the same that may maintain surface liquid repellency during high-illuminance exposure.

### (b) Description of the Related Art

A light emitting device includes an anode, a cathode, and a light emitting layer formed between them, and excitons generated holes injected from the anode and electrons injected from the cathode being combined in the light emitting layer are changed to a ground state from an excited state, releasing energy to emit light.

Since the light emitting device may be driven with low voltage, may be configured to be lightweight and thin, and may have excellent characteristics such as a viewing angle, a contrast, and a response speed, a range of applications thereof is increasing from a personal portable device to a television (“TV”).

An inkjet process may be used to form a light emitting layer during a manufacturing process of the light emitting element. In this case, a partition wall having a width of a certain size or more is required to prevent an inkjet solution from penetrating neighboring pixels. It is also desirable that an inkjet solution is formed within a partition wall and does not flow to the surroundings.

The above information disclosed in this Background section is only for enhancement of understanding of the background of the disclosure, and therefore it may contain information that does not form the prior art that is already known in this country to a person of ordinary skill in the art.

### SUMMARY

Embodiments are to provide a resin composition and a display device manufactured using the same that may maintain liquid repellency even during high-illuminance exposure.

An embodiment provides a resin composition including: a liquid repellent, where the liquid repellent includes a compound represented by Chemical Formula 1 below or a compound represented by Chemical Formula 2 below:

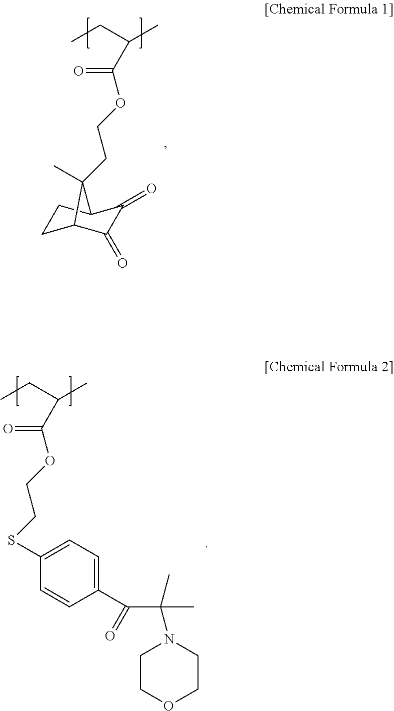

A content of the compound represented by Chemical Formula 1 or the compound represented by Chemical Formula 2 may be 10 percentages by weight (wt %) or less based on the total content of the liquid repellent.

A content of the compound represented by Chemical Formula 1 or the compound represented by Chemical Formula 2 may be 0.5 wt % or less based on the total content of the resin composition.

An acid value of the liquid repellent may be 20 milligrams of potassium hydroxide per gram (mg KOH/g) to 150 mg KOH/g.

A molecular weight of the liquid repellent may be 30,000 to 150,000.

The liquid repellent may further include a compound represented by Chemical Formula 3 below and a compound represented by Chemical Formula 4 below:

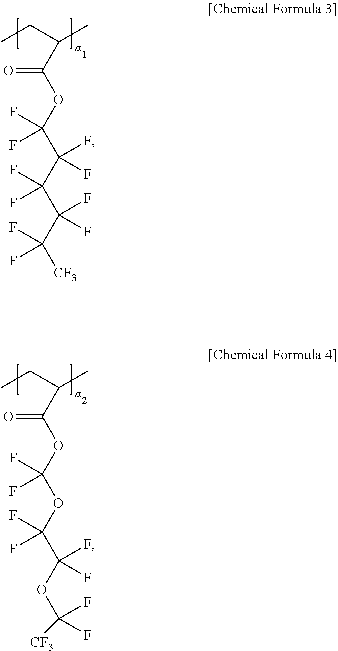

where a1 and a2 may each independently be 1 to 10,000.

The liquid repellent may further include a compound represented by Chemical Formula 5 below:

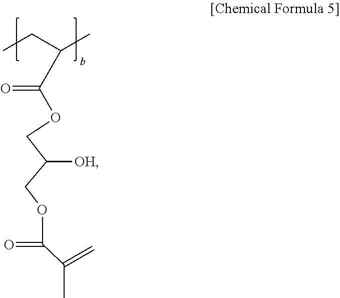

where b may be 1 to 10,000.

The liquid repellent may further include a compound represented by Chemical Formula 6 below:

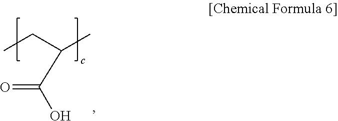

where c may be 1 to 10,000.

Another embodiment provides a manufacturing method of a display device, including: coating a resin composition on a substrate, and exposing and developing the resin composition, where the exposing is performed using a light exposer with an illuminance of 30 mW/cm² or more, the resin composition includes a liquid repellent, and the liquid repellent includes a compound represented by Chemical Formula 1 or a compound represented by Chemical Formula 2:

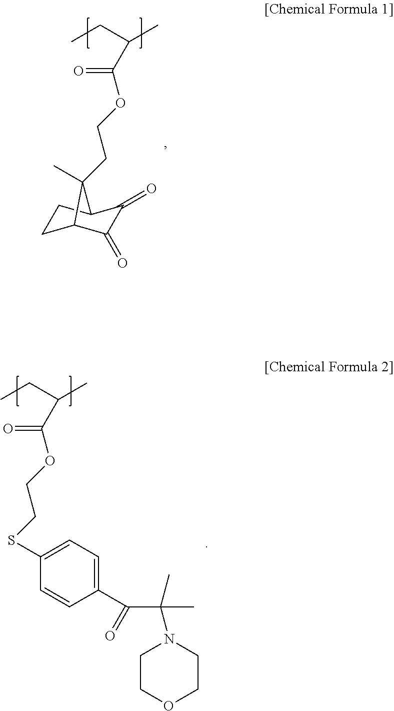

A content of the compound represented by Chemical Formula 1 or the compound represented by Chemical Formula 2 may be 10 wt % or less based on the total content of the liquid repellent.

A content of the compound represented by Chemical Formula 1 or the compound represented by Chemical Formula 2 may be 0.5 wt % or less based on the total content of the resin composition.

An acid value of the liquid repellent may be 20 mg KOH/g to 150 mg KOH/g.

A molecular weight of the liquid repellent may be 30,000 to 150,000.

The liquid repellent may further include a compound represented by Chemical Formula 3 below and a compound represented by Chemical Formula 4 below:

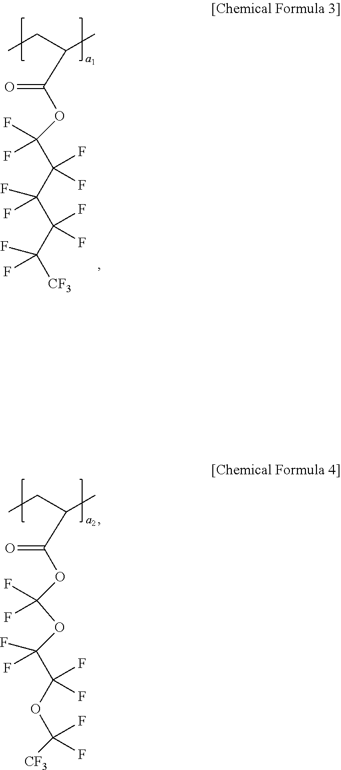

where a1 and a2 may each independently be 1 to 10,000.

The liquid repellent may further include a compound represented by Chemical Formula 5 below:

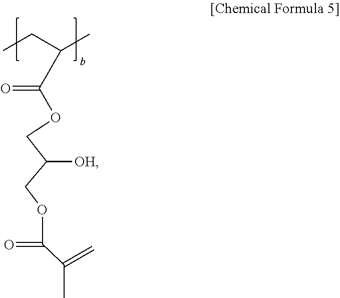

where b may be 1 to 10,000.

The liquid repellent may further include a compound represented by Chemical Formula 6 below:

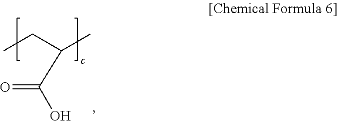

where c may be 1 to 10,000.

The manufacturing method of the display device may further include after the coating of the resin composition on the substrate, and pre-baking the coated resin composition, wherein the liquid repellent may move to a surface of the resin composition in the pre-baking.

Another embodiment provides a display device including: a substrate; a transistor disposed on the substrate; and a first electrode connected to the transistor; a partition wall disposed on the first electrode and defining an opening therein; a light emitting layer disposed at the opening of the partition wall; and a second electrode disposed on the light emitting layer, wherein the partition wall includes a compound represented by Chemical Formula 1 below or a compound represented by Chemical Formula 2 below:

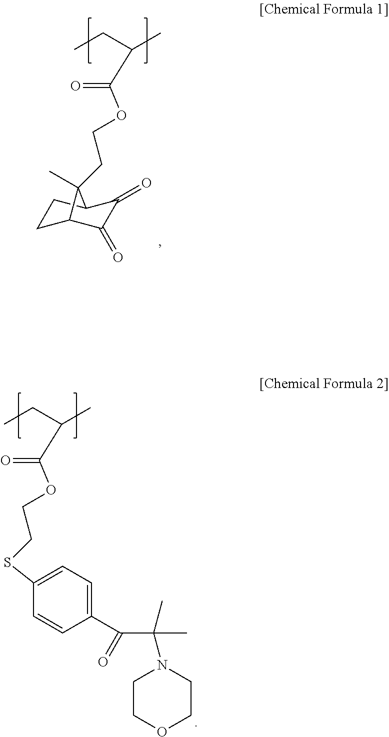

A concentration of the compound represented by Chemical Formula 1 or the compound represented by Chemical Formula 2 in a lower area of the partition wall disposed close to the substrate may be smaller than a concentration of the compound represented by Formula 1 or the compound represented by Formula 2 in an upper area of the partition wall disposed away from the substrate.

A surface energy of the partition wall may gradually decrease in a direction away from the substrate.

According to the embodiments, it is possible to provide a resin composition and a display device formed using the same that may maintain liquid repellency even during high-illuminance exposure.

### BRIEF DESCRIPTION OF THE DRAWINGS

FIG. 1 to FIG. 4 illustrate processes of forming a partition wall by using a resin composition according to an embodiment.

FIG. 5 and FIG. 6 are drawings in which a change in surface energy for each integrated amount of light according to illuminance is measured while varying the illuminance of an exposure device.

FIG. 7 and FIG. 8 schematically show a degree of curing in a resin when exposed to low and high luminance.

FIG. 9 schematically illustrates a curing process of a resin composition according to an embodiment.

FIG. 10 illustrates a schematic cross-section of a display device according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a resin composition and a forming method of a display device using the resin composition according to an embodiment of the present disclosure will be described in detail with reference to the accompanying drawings.

The resin composition according to the present embodiment may be a resin composition for forming a partition wall of a display device. Specifically, it is to provide a resin composition that may maintain surface liquid repellency even when exposed to high illuminance.

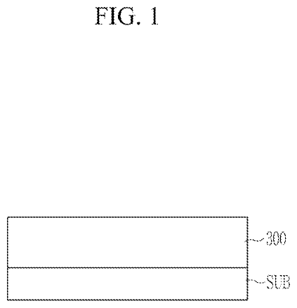

FIG. 1 to FIG. 4 schematically illustrate processes of forming a partition wall by using a resin composition according to an embodiment. Referring to FIG. 1, a resin composition 300 is coated on a substrate SUB and pre-baked. During this process, a liquid repellent included in the resin composition 300 may move to the surface.

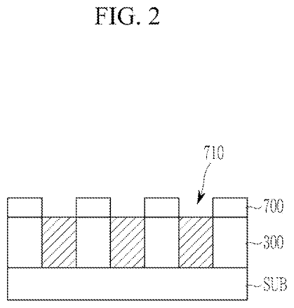

Next, a mask 700 is disposed on the resin composition 300 and exposed. An opening 710 is formed in the mask 700, so that the resin composition 300 corresponding to the opening 710 is exposed. In FIG. 2, the exposed areas are indicated by hatching.

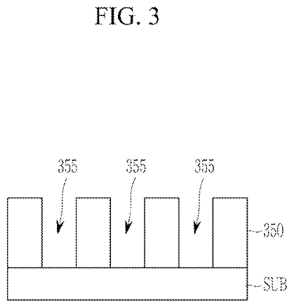

Next, referring to FIG. 3, the resin composition 300 is developed. In this case, the exposed area of the resin composition 300 is developed to form a partition wall 350 including an opening 355.

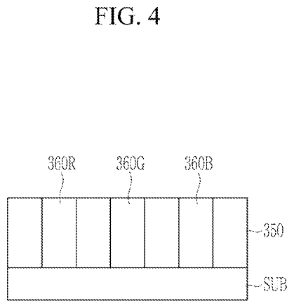

Next, referring to FIG. 4, a red light emitting layer 360R, a green light emitting layer 360G, and a blue light emitting layer 360B are formed in the openings 355, respectively, through an inkjet process. Each of the light emitting layers may include quantum dots.

In this case, in order to form the red light emitting layer 360R, the green light emitting layer 360G, and the blue light emitting layer 360B in the openings 355 of the partition wall 350 by the inkjet process, it is desirable that an upper portion of the partition wall 350 filled with each ink has a hydrophobic property. To this end, it is desirable that the surface energy required for the upper portion of the partition wall 350 is 25 dynes per centimeter (dyne/cm) or less. In addition, it is desirable that the inside of the opening 355 of the partition wall 350 where the ink is filled has a high surface energy so that wetting defects do not occur. Specifically, the surface energy inside the opening 355 of the partition wall 350 may be 40 dyne/cm or more.

In the exposure process for forming the partition wall, the lower the illuminance of the exposure device, the easier it is to maintain the surface liquid repellency.

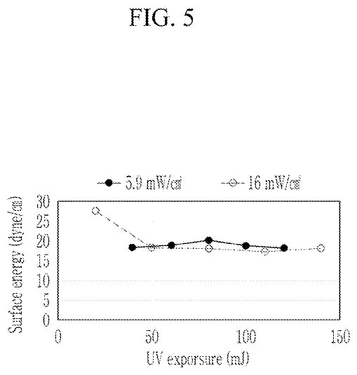

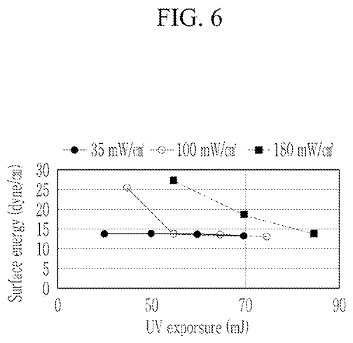

FIG. 5 and FIG. 6 are drawings in which a change in surface energy for each integrated amount of light according to illuminance is measured while varying the illuminance of an exposure device. Referring to FIG. 5, when the illuminance of the exposure device was 5.9 milliwatts per square centimeters (mW/cm²), there was little change in surface energy even if the integrated light amount increased, but when the illuminance of the exposure device increased to 16 mW/cm², there was a change in surface energy according to the increase in integrated light.

Even in FIG. 6, when the exposure amount was 35 mW/cm², there was substantially no change in surface energy for each integrated light amount, but when the integrated light amount increased to 100 mW/cm² or 180 mW/cm², the surface energy changed according to the integrated light amount.

This is because the molecular weight of the photocurable polymer network in the resin decreases when exposed at high illuminance compared to exposure at low illuminance.

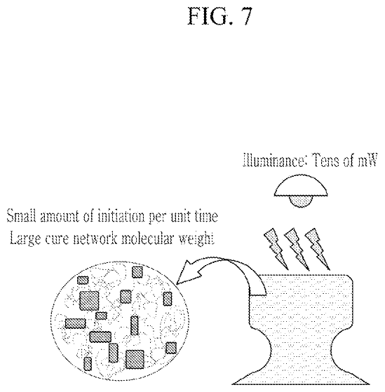

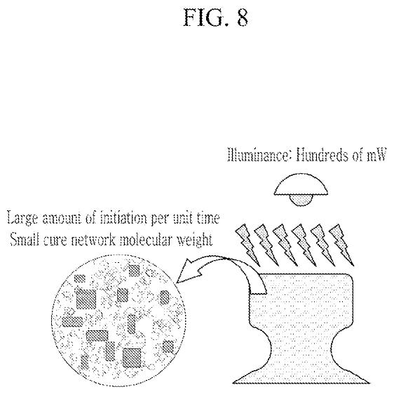

FIG. 7 and FIG. 8 schematically show a degree of curing in a resin when exposed to low and high luminance. FIG. 7 shows a case of low-illuminance exposure with several tens of mW/cm², and FIG. 8 shows a case of high-illuminance exposure with hundreds of mW/cm².

Comparing FIG. 7 with FIG. 8, the amount of initiation per unit time is small and the molecular weight of the curing network is high, in low light exposure. However, during the high-illuminance exposure of FIG. 8, the amount of initiation per unit time is high and the molecular weight of the curing network is low. As described above, since the molecular weight of the polymer network is low during high-illuminance exposure, it is easy for the developer (i.e., developer solution) to penetrate the exposure portion. When the developer permeates the exposure portion in this way, the hardness of the resin deteriorates, and the possibility of surface loss increases in proportion to the cleaning pressure during cleaning. When the surface loss occurs, there is a problem in that surface energy is lowered and liquid repellency is reduced.

However, the resin composition according to the present embodiment includes a photoinitiator to increase surface curing, and lowers an acid value of the liquid repellent itself to minimize penetration of the developer during development, thereby improving liquid repellency reduction during high-illuminance exposure.

Hereinafter, components of the resin composition according to the present embodiment will be described in detail. The resin composition according to the present embodiment may include a compound represented by Chemical Formula 1 or Chemical Formula 2 below.

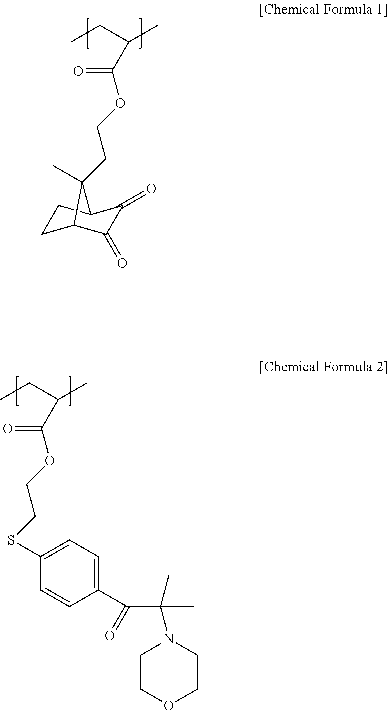

The compound represented by Chemical Formula 1 or Chemical Formula 2 plays the same role as the photoinitiator, and may increase the degree of surface curing of the resin by making the liquid repellent included in the resin composition more sensitively react to UV during exposure. That is, the resin composition including the compound represented by Chemical Formula 1 or the compound represented by Chemical Formula 2 may increase the durability of the film by increasing the degree of surface curing during curing, and may effectively prevent deterioration of liquid repellency due to physical surface loss during cleaning after development.

In this case, the content of the compound represented by Chemical Formula 1 or the compound represented by Chemical Formula 2 may be 0.5 percentages by weight (wt %) or less based on the total weight of the resin composition. When the content of the compound represented by Chemical Formula 1 or the compound represented by Chemical Formula 2 exceeds 0.5 wt % based on the total weight of the resin composition, the resin composition may be excessively hardened and may not be easily etched.

In addition, the resin composition according to the present embodiment may further include a compound represented by Chemical Formula 3 to Chemical Formula 6 below.

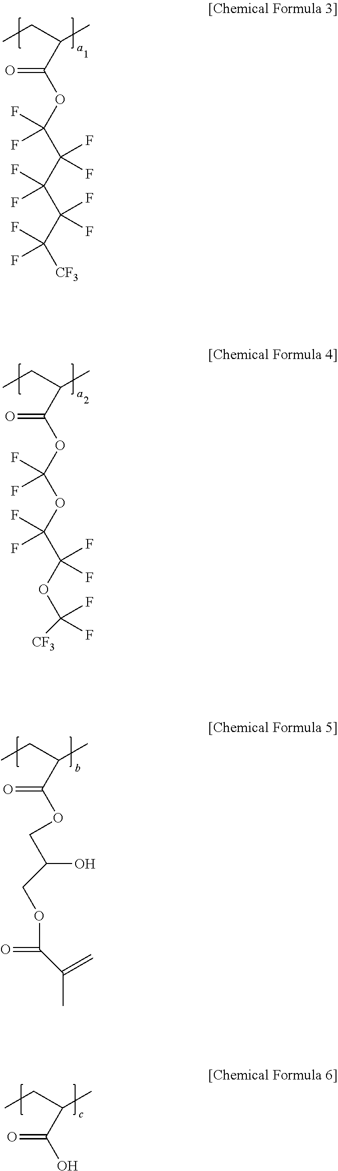

In Chemical Formula 3 to Chemical Formula 6, a1, a2, b, and c may each be 1 to 10,000.

The compound represented by Chemical Formula 3 and the compound represented by Chemical Formula 4 are compounds that make the resin composition have liquid repellency. The compound represented by Chemical Formula 5 is a compound for forming a polymer network upon light irradiation and includes an acrylate group. The compound represented by Chemical Formula 6 is a component for imparting an acid value to the resin composition.

All of the compounds represented by Chemical Formula 1 to Chemical Formula 6 are collectively referred to as a liquid repellent, and it is desirable that the content of the liquid repellent does not exceed 5 wt % based on the total content of the resin composition. When the content of the liquid repellent exceeds 5 wt % based on the total content of the resin composition, it may affect the film characteristics of the resin composition. In addition, the content of the compound represented by Chemical Formula 1 or the compound represented by Chemical Formula 2 is desirably within 10 wt % of the total content of the liquid repellent. When the content of the compound represented by Chemical Formula 1 or the compound represented by Chemical Formula 2 exceeds 10 wt % based on the total content of the liquid repellent, the resin composition may be excessively cured and may not be easily etched.

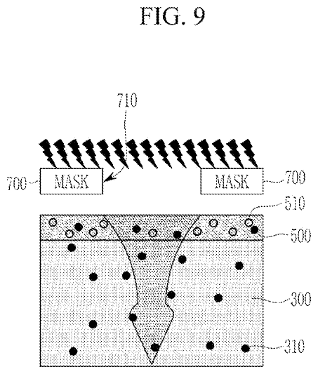

FIG. 9 schematically illustrates a curing process of a resin composition according to an embodiment. Referring to FIG. 9, during the curing process of the resin composition 300, a liquid repellent 500 rises to an upper portion of the resin composition. Photoinitiators 310 included in the resin composition 300 are evenly disposed throughout the resin composition 300, but like the present embodiment, photoinitiators 510 included in the liquid repellent 500 are disposed at the upper portion of the resin composition together with the liquid repellent 500. The photoinitiator 510 included in the liquid repellent 500 may be a compound represented by Chemical Formula 1 or a compound represented by Chemical Formula 2.

As described above, since the photoinitiators 510 included in the liquid repellent 500 are disposed at the upper portion of the resin composition 300, the liquid repellent 500 may react sensitively to light irradiated during curing to increase the degree of surface curing. Accordingly, the surface hardening degree and durability increase, so it is possible to effectively prevent deterioration in liquid repellency due to physical damage during cleaning after development.

In this case, the acid value of the liquid repellent 500 included in the resin composition 300 according to the present embodiment may be 20 milligrams of potassium hydroxide per gram (mg KOH/g) to 150 mg KOH/g. If the acid value is less than 20 mg KOH/g, when the molecular weight increases, the solubility in the developing solution decreases and thus the developing time must be increased, which is not desirable. In addition, if the acid value exceeds 150 mg KOH/g, no additives remain on the surface, so that liquid repellency may be deteriorated.

In addition, the molecular weight of the liquid repellent 500 included in the resin composition 300 according to the present embodiment may be 30,000 to 150,000. When the molecular weight thereof exceeds 150,000, the ease of synthesis and storage stability decrease, which is not desirable.

As described above, when the acid value of the liquid repellent 500 exceeds 20 mg KOH/g and the molecular weight thereof is 30,000 or more, the surface energy of the partition wall formed by the resin composition may be reduced and the surface liquid repellency may be increased.

Hereinafter, a manufacturing method of the display device according to the present embodiment will be described. The manufacturing method of the display device according to the present embodiment will be mainly described with a method of forming a partition wall using a resin composition.

The manufacturing method of the display device according to the present embodiment includes forming a resin composition on a substrate, and exposing and developing the resin composition, wherein the resin composition includes the compound represented by Chemical Formula 1 or Chemical Formula 2.

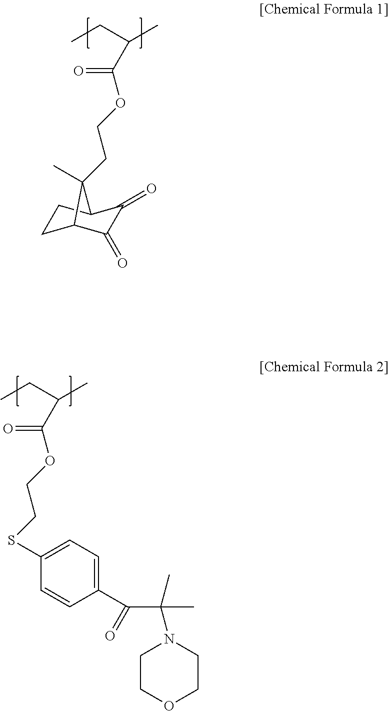

That is, in the manufacturing method according to the present embodiment, the resin composition has the same composition as described above, and detailed descriptions of the same constituent elements are omitted.

FIG. 1 to FIG. 4 show the method of forming the partition wall according to the present embodiment. Referring to FIG. 1, the resin composition 300 is disposed on the substrate SUB. In this case, the composition of the resin composition 300 is as described above. Detailed descriptions of the same constituent elements will be omitted.

Next, referring to FIG. 2, the mask 700 is disposed and exposed on the resin composition 300. The opening 710 is formed in the mask 700, so that the resin composition 300 corresponding to the opening 710 is exposed. In this case, the resin composition 300 according to the present embodiment includes the compound represented by Chemical Formula 1 or the compound represented by Chemical Formula 2, and thus the surface curing degree increases. In the present embodiment, exposure may be performed using a light exposer with an illuminance of 30 mW/cm² or more.

Next, referring to FIG. 3, the resin composition 300 is developed. In this case, since the acid value of the liquid repellent included in the resin composition 300 according to the present embodiment is 20 mg KOH/g to 150 mg KOH/g, penetration of the developing solution into the resin composition 300 may be minimized. The exposed area of the resin composition 300 is developed to form the partition wall 350 including the opening 355.

Next, referring to FIG. 4, the red light emitting layer 360R, the green light emitting layer 360G, and the blue light emitting layer 360B are formed in the openings 355, respectively, through an inkjet process. Each of the light emitting layers may include quantum dots. In this case, the partition wall 350 formed of the resin composition according to the present embodiment may have a high hydrophobic surface.

Hereinafter, a display device according to the present embodiment will be briefly described below.

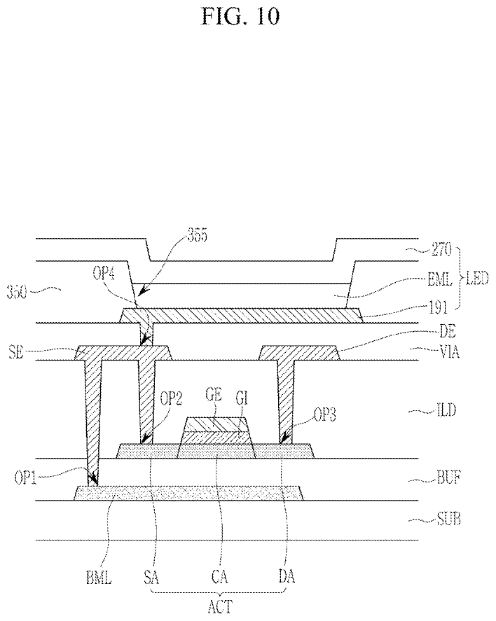

FIG. 10 illustrates a schematic cross-section of a display device according to an embodiment. Referring to FIG. 10, the substrate SUB is disposed. The substrate SUB may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. The substrate SUB may be a rigid substrate, or a flexible substrate that is bendable, foldable, or rollable. The substrate SUB may be single-layered or multi-layered. The substrate SUB may be a substrate in which at least one base layer and at least one inorganic layer, which include polymer resins sequentially stacked, are alternately stacked.

A light blocking layer BML is disposed on the substrate SUB. The light blocking layer BML may include aluminum (Al), silver (Ag), magnesium (Mg), gold (Au), nickel (Ni), chromium (Cr), calcium (Ca), molybdenum (Mo), titanium (Ti), tungsten (W), and/or copper (Cu) and a metal oxide, and may have a single-layered or multi-layered structure including them.

A buffer layer BUF is disposed on the light blocking layer BML. The buffer layer BUF may include a silicon oxide (SiOx), a silicon nitride (SiNx), a silicon oxynitride (SiOxNy), or amorphous silicon (Si).

The buffer layer BUF may define a first opening OP1 therein overlapping the light blocking layer BML in a plan view. A source electrode SE may be connected to the light blocking layer BML in the first opening OP1.

A semiconductor layer ACT is disposed on the buffer layer BUF. The semiconductor layer ACT may include polycrystalline silicon. The semiconductor layer ACT may include a channel area CA overlapping a gate electrode GE in a plan view, and a source area SA and a drain area DA disposed at respective sides of the channel area.

A gate insulating film GI is disposed on the semiconductor layer ACT. The gate insulating film GI may include a silicon oxide (SiOx), a silicon nitride (SiNx), and a silicon oxynitride (SiOxNy), and may have a single-layered or multi-layered structure including them.

The gate insulating film GI may be disposed to overlap the channel area CA of the semiconductor layer ACT in a plan view. A gate conductive layer including the gate electrode GE may be disposed on the gate insulating film GI. The gate conductive layer may include molybdenum (Mo), aluminum (Al), copper (Cu), titanium (Ti), and a metal oxide, and may have a single layered or multi-layered structure including the same.

The gate electrode GE may be formed in the same process as the gate insulating film GI to have the same planar shape. The gate electrode GE may be disposed to overlap the semiconductor layer ACT in a direction perpendicular to a surface of the substrate SUB (i.e., in a plan view).

An interlayer-insulating film ILD may be disposed on the semiconductor layer ACT and the gate electrode GE. The interlayer-insulating film ILD may include a silicon oxide (SiOx), a silicon nitride (SiNx), and a silicon oxynitride (SiOxNy), and may have a single-layered or multi-layered structure including them. When the interlayer-insulating film ILD has a multi-layered structure including a silicon nitride and a silicon oxide, a layer including the silicon nitride may be disposed closer to the substrate SUB than a layer including the silicon oxide.

The interlayer-insulating film ILD may define a first opening OP1 therein overlapping the light blocking layer BML, a second opening OP2 therein overlapping the source area SA of the semiconductor layer ACT, and a third opening OP3 therein overlapping the drain area DA thereof in a plan view.

A data conductive layer including the source electrode SE and the drain electrode DE is disposed on the interlayer-insulating film ILD. The data conductive layer may include aluminum (Al), silver (Ag), magnesium (Mg), gold (Au), nickel (Ni), chromium (Cr), calcium (Ca), molybdenum (Mo), titanium (Ti), tungsten (W), and/or copper (Cu), and a metal oxide, and may have a single-layered or multi-layered structure including them.

The source electrode SE may contact the light blocking layer BML at the first opening OP1, and may contact the source area SA of the semiconductor layer ACT in the second opening OP2. The drain electrode DE may contact the drain area DA of the semiconductor layer ACT at the third opening OP3.

An insulating film VIA is disposed on the data conductive layer. In an embodiment, the insulating film VIA may include an organic insulating material such as a general purpose polymer such as poly(methyl methacrylate) (“PMMA”) or polystyrene (“PS”), a polymer derivative having a phenolic group, an acryl-based polymer, an imide-based polymer, a polyimide, and a siloxane-based polymer.

The insulating film VIA may define a fourth opening OP4 therein overlapping the source electrode SE in a plan view. A first electrode 191 is disposed on the insulating film VIA. A light emitting layer EML and a second electrode 270 may be disposed on the first electrode 191. The first electrode 191, the light emitting layer EML, and the second electrode 270 may form a light emitting element LED.

The partition wall 350 disposed on the first electrode 191 is included, and the light emitting layer EML is disposed in the opening 355 of the partition wall 350. In this case, the partition wall 350 may be formed of the resin composition described above.

That is, the partition wall 350 may include a compound represented by Chemical Formula 1 or Chemical Formula 2 below.

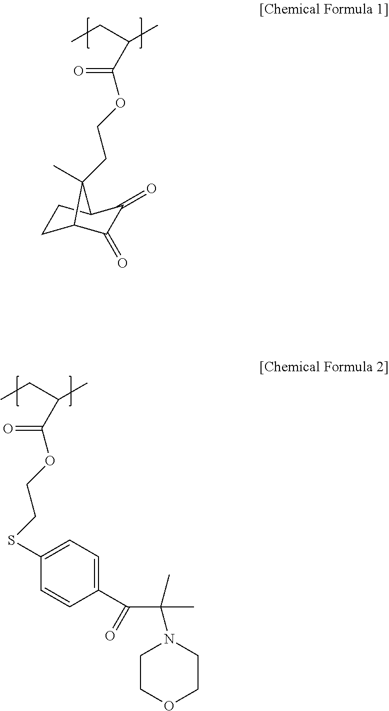

In addition, the partition wall 350 may further include a compound represented by Chemical Formula 3 to Chemical Formula 6 below.

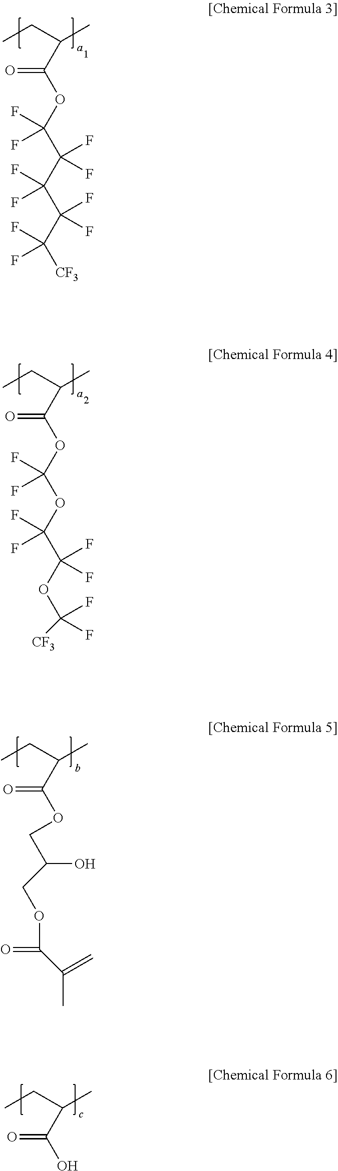

In Chemical Formula 3 to Chemical Formula 6, a1, a2, b, and c may each be 1 to 10,000.

The upper surface of the partition wall 350, that is, the side farther from the substrate SUB of the sides of the partition walls 350, may be more hydrophobic than the side (i.e., lower surface) closer to the substrate SUB. This is because most of the liquid repellent moves to the upper surface during the coating and pre-baking process for forming the partition wall 350 as described above. That is, the surface energy of the side (i.e., upper surface) of the partition wall 350 disposed farther from the substrate SUB may be lower than the surface energy of the side thereof disposed closer to the substrate SUB. In this case, the surface energy may have a distribution that gradually decreases as the distance from the substrate SUB increases.

In addition, in the partition wall 350 according to the present embodiment, the compound represented by Chemical Formula 1 or the compound represented by Chemical Formula 2 may be mainly disposed on the upper surface of the partition wall 350 (a surface disposed far from the substrate SUB). That is, the concentration (i.e., content per unit volume of the partition wall 350) of the compound represented by Chemical Formula 1 or the compound represented by Chemical Formula 2 in the lower portion of the partition wall 350 is lower than the concentration of the compound represented by Chemical Formula 1 or the compound represented by Chemical Formula 2 in the upper portion of the partition wall 350. A general photoinitiator is evenly disposed throughout the partition wall 350, but the photoinitiator represented by Chemical Formula 1 or Chemical Formula 2 according to the present embodiment is mainly disposed on the upper portion of the partition wall 350. This is because the photoinitiator represented by Chemical Formula 1 or Chemical Formula 2 is included in the liquid repellent to move to the upper portion of the partition wall 350 together with the liquid repellent.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A resin composition comprising
a liquid repellent,
wherein the liquid repellent includes a compound represented by Chemical Formula 1 below or a compound represented by Chemical Formula 2 below:

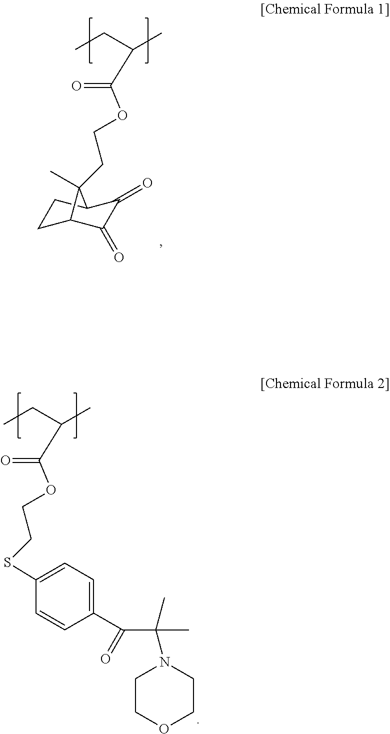

2. The resin composition of claim 1, wherein
a content of the compound represented by Chemical Formula 1 or the compound represented by Chemical Formula 2 is 10 percentages by weight (wt %) or less based on a total content of the liquid repellent.

3. The resin composition of claim 1, wherein
a content of the compound represented by Chemical Formula 1 or the compound represented by Chemical Formula 2 is 0.5 wt % or less based on a total content of the resin composition.

4. The resin composition of claim 1, wherein
an acid value of the liquid repellent is 20 milligrams of potassium hydroxide per gram (mg KOH/g) to 150 mg KOH/g.

5. The resin composition of claim 1, wherein
a molecular weight of the liquid repellent is 30,000 to 150,000.

6. The resin composition of claim 1, wherein
the liquid repellent further includes:
a compound represented by Chemical Formula 3 below and a compound represented by Chemical Formula 4 below: 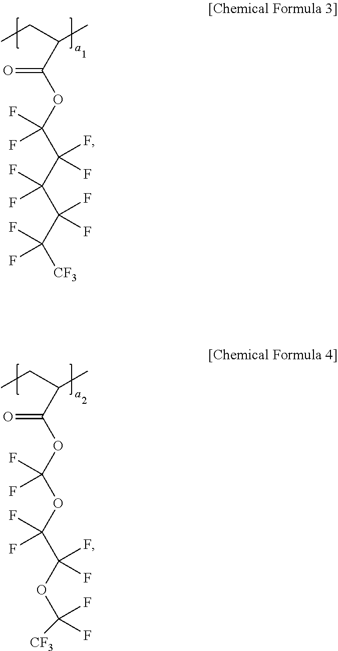
where a1 and a2 may each independently be 1 to 10,000.

7. The resin composition of claim 1, wherein
the liquid repellent further includes a compound represented by Chemical Formula 5 below: 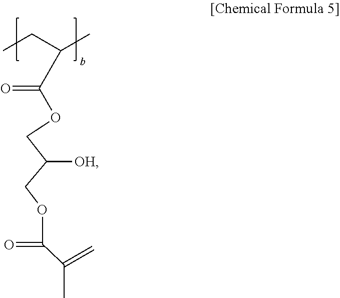
where b is 1 to 10,000.

8. The resin composition of claim 1, wherein
the liquid repellent further includes a compound represented by Chemical Formula 6 below: 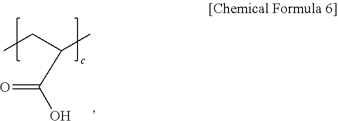
where c is 1 to 10,000.

9. A manufacturing method of a display device, comprising:
coating a resin composition on a substrate; and
exposing and developing the resin composition,
wherein the exposing is performed using a light exposer with illuminance of 30 mW/cm² or more,
the resin composition includes a liquid repellent, and
the liquid repellent includes a compound represented by Chemical Formula 1 or a compound represented by Chemical Formula 2:

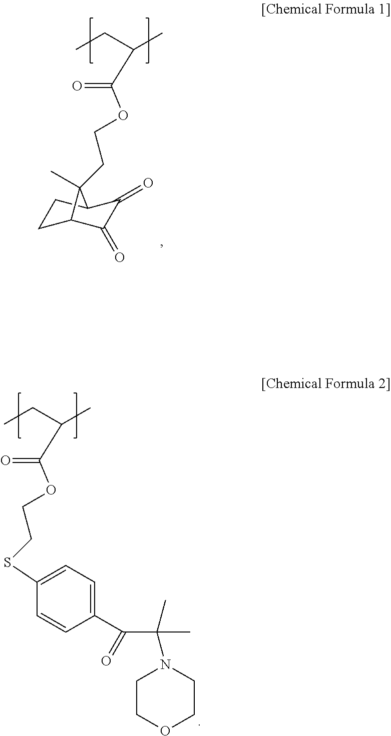

10. The manufacturing method of the display device of claim 9, wherein
a content of the compound represented by Chemical Formula 1 or the compound represented by Chemical Formula 2 is 10 wt % or less based on a total content of the liquid repellent.

11. The manufacturing method of the display device of claim 9, wherein
a content of the compound represented by Chemical Formula 1 or the compound represented by Chemical Formula 2 is 0.5 wt % or less based on a total content of the resin composition.

12. The manufacturing method of the display device of claim 9, wherein
an acid value of the liquid repellent is 20 mg KOH/g to 150 mg KOH/g.

13. The manufacturing method of the display device of claim 9, wherein
a molecular weight of the liquid repellent is 30,000 to 150,000.

14. The manufacturing method of the display device of claim 9, wherein
the liquid repellent further includes:
a compound represented by Chemical Formula 3 below and a compound represented by Chemical Formula 4 below: 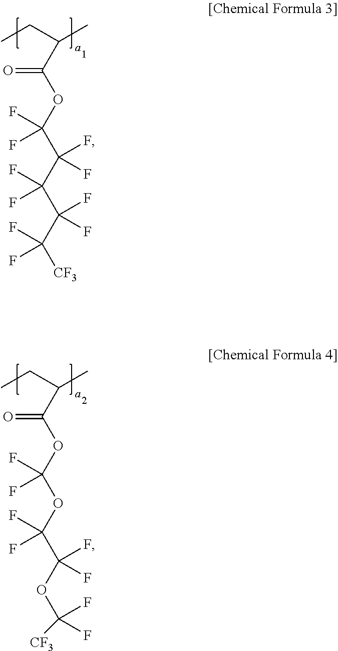
where a1 and a2 are each independently 1 to 10,000.

15. The manufacturing method of the display device of claim 9, wherein
the liquid repellent further includes a compound represented by Chemical Formula 5 below: 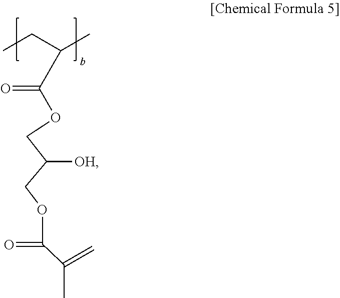
where b may be 1 to 10,000.

16. The manufacturing method of the display device of claim 9, wherein
the liquid repellent further includes a compound represented by Chemical Formula 6 below: 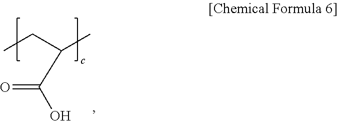
where c is 1 to 10,000.

17. The manufacturing method of the display device of claim 9, further comprising,
after the coating of the resin composition on the substrate, pre-baking the coated resin composition,
wherein the liquid repellent moves to a surface of the resin composition in the pre-baking.

18. A display device comprising:
a substrate;
a transistor disposed on the substrate;
a first electrode connected to the transistor;
a partition wall disposed on the first electrode and defining an opening therein;
a light emitting layer disposed at the opening of the partition wall; and
a second electrode disposed on the light emitting layer,
wherein the partition wall includes a compound represented by Chemical Formula 1 below or a compound represented by Chemical Formula 2 below:

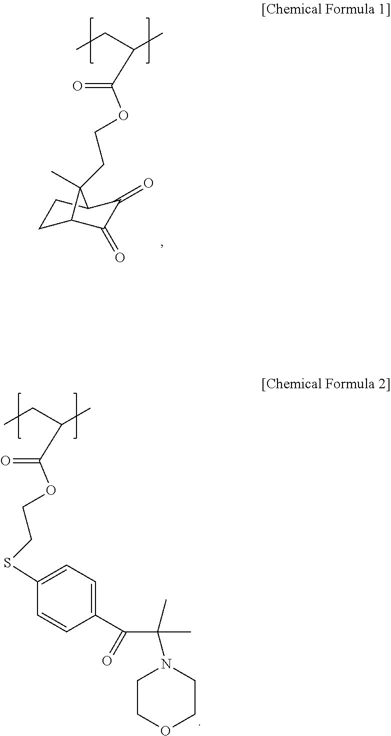

19. The display device of claim 18, wherein
a concentration of the compound represented by Chemical Formula 1 or the compound represented by Chemical Formula 2 in a lower area of the partition wall disposed close to the substrate is smaller than
a concentration of the compound represented by Formula 1 or the compound represented by Formula 2 in an upper area of the partition wall disposed away from the substrate.

20. The resin composition of claim 18, wherein
surface energy of the partition wall gradually decreases in a direction away from the substrate.
